(19) United States
(12) Patent Application Publication
(10) Pub. No.: US 2008/0035059 A1
(43) Pub. Date: Feb. 14, 2008

(54) Chemical vapor deposition reactor

(75) Inventors: Ming-Hui Wang, Taipei City (TW); Hsiao-Kuo Chang, Taoyuan City (TW); Kuan-Hung Lin, Banciao City (TW)

Correspondence Address: BACON & THOMAS, PLLC, 625 SLATERS LANE, FOURTH FLOOR, ALEXANDRIA, VA, 22314, US

(73) Assignee: Kinik Company, Taipei (TW)

(21) Appl. No.: 11/544,557

(22) Filed: Oct. 10, 2006

(30) Foreign Application Priority Data
Aug. 9, 2006 (TW) 095129181

(51) Int. Cl. C23C 16/00

(52) U.S. Cl. 118/723 HC

(57) ABSTRACT

A CVD (chemical vapor deposition) reactor having a horizontal coating plane and power source-controlled hot filaments is disclosed. The CVD reactor has a chamber, rotating electrodes provided inside the chamber, hot filaments connected to the rotating electrodes to form a horizontal coating plane above a substrate, and a rotating power source, which is controlled to rotate the rotating electrodes and to further stretch the hot filaments when the hot filaments expand due to a temperature change, prohibiting the hot filaments from touching the substrate.

### BACKGROUND OF THE INVENTION

1. Field of the Invention

The present invention relates to an equipment for chemical vapor deposition and more particularly, to a CVD (chemical vapor deposition) reactor having a horizontal coating plane and power source-controlled hot filaments.

2. Description of Related Art

Conventional industrial thin film depositions can be divided into two types subject to the presence of a chemical reaction or not during thin film deposition, namely, PVD (physical vapor deposition) and CVD (chemical vapor deposition).

Hot Filament CVD (HFCVD) is a kind of chemical vapor deposition. Because of the advantages of high covering power, high uniformity, high purity, and big area deposition, Hot Filament CVD is intensively used in making diamond thin films and polysilicon materials.

Basically, Hot Filament CVD (HFCVD) uses the surface high temperature of hot filaments in the chamber of a reactor to cause pyrolysis (thermal cracking) of the reaction gas that passes through the hot filaments so that atoms are deposited to form a thin film on the substrate.

In actual manufacturing application, the reaction temperature of the substrate in the reaction chamber of the reactor must be controlled within the optimal manufacturing conditions so that the quality parameters of purity, thickness and uniformity of the deposited thin film can be controlled.

However, during the deposition operation of the Hot Filament CVD reactor, the hot filament surface temperature in the reaction chamber may be over 2400° C. (hot filament temperature may be changed subject to the material to be coated). The hot filaments expand under this high temperature, and may vibrate subject to the flowing of the reaction gas, resulting in uneven thickness of deposited thin film or breaking of the hot filaments to damage the substrate.

In order to eliminate the aforesaid problem, spring means or weights may be added to the ends of the hot filaments. However, these measures are still not satisfactory in function.

Therefore, it is desirable to provide a chemical vapor deposition reactor that eliminates the aforesaid problems.

### SUMMARY OF THE INVENTION

The present invention has been accomplished under the circumstances in view. According to one embodiment of the present invention, the chemical vapor deposition reactor comprises a chamber, at least two electrodes, a plurality of hot filaments, and a rotary power source.

The chamber defines therein an enclosed space. The substrate for deposition treatment is placed in the enclosed space. The substrate has a top surface for coating.

Further, the at least two electrodes are arranged inside the enclosed space. The at least two electrodes include at least one rotating electrode.

Further, the hot filaments each have two ends respectively connected to the at least two electrodes, having a predetermined tension. The hot filaments are kept spaced above the top surface of the substrate at a predetermined distance.

Further, the rotating power source is controllable to rotate the at least one rotating electrode in a particular direction, to further maintain the predetermined distance between the hot filaments and the substrate.

When the hot filaments expand due to a high temperature in the chamber, the rotating electrodes are rotated to stretch the hot filaments, thereby maintaining the predetermined distance between the hot filaments and the substrate.

The invention further comprises at least one sensor adapted to detect variation of the distance between the hot filaments and the top surface of the substrate, and to output a corresponding detection signal.

The at least one sensor can be optical sensor, thermocouple sensor, or any of a variety of other equivalent sensor means.

The invention further comprises a controller adapted to receive the detection signal outputted from the at least one sensor and to control the operation of the rotating power source subject to the detection signal.

Further, the detection signal from the at least one sensor can be directly fed back to the rotating power source for control. This control method is superior to the conventional technique of using spring or weight to control hot filaments in one single direction without feedback signal, and can accurate maintain the predetermined distance between the hot filaments and the substrate.

The invention may use at least one stress sensor to detect the tension of each hot filament and to output a corresponding detection signal. Further, the detection signal can be sent to a controller to control the operation of the rotating power source. Alternatively, the detection signal can be directly fed back to the rotating power source to control the operation of the rotating power source.

Further, the rotating power source can be an electric motor, a pneumatic cylinder, a hydraulic cylinder, or any of a variety of other equivalent rotating power sources.

Further, each hot filament can be formed of one single filament or a number of filaments. When a number of hot wires are used to constitute one hot filament, the hot wires are twisted together, enhancing the strength and high temperature physical performance of the hot filament.

### BRIEF DESCRIPTION OF THE DRAWINGS

FIG. 1 is a schematic drawing of a chemical vapor deposition reactor in accordance with a first embodiment of the present invention.

FIG. 2 is a schematic drawing of a chemical vapor deposition reactor in accordance with a second embodiment of the present invention.

FIG. 3 is a schematic drawing of a chemical vapor deposition reactor in accordance with a third embodiment of the present invention.

FIG. 4 is an enlarged view of a part of FIG. 1, showing the structure of the hot filaments.

### DETAILED DESCRIPTION OF THE PREFERRED EMBODIMENT

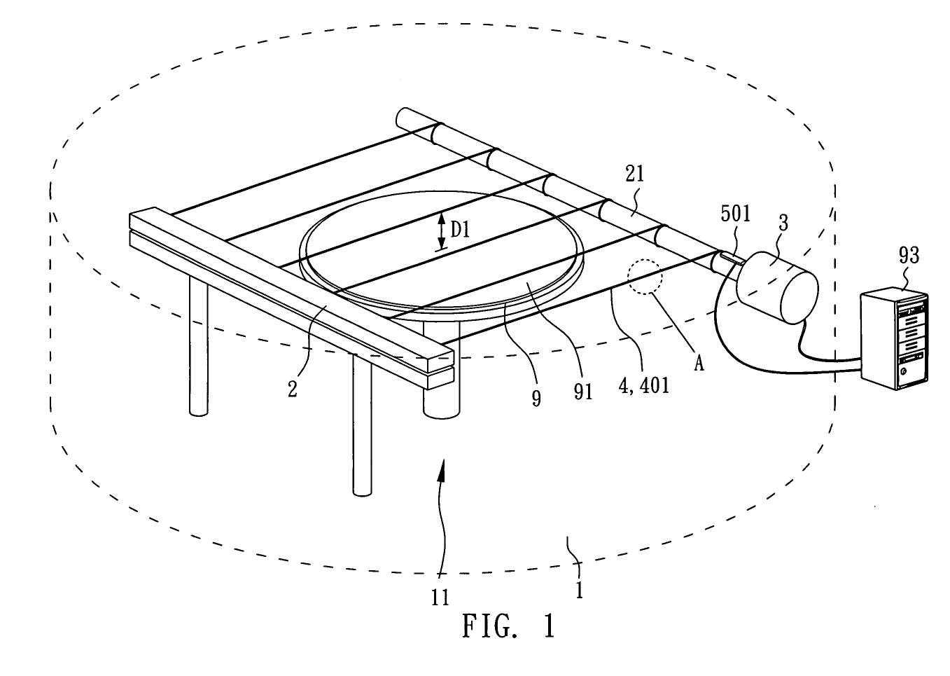

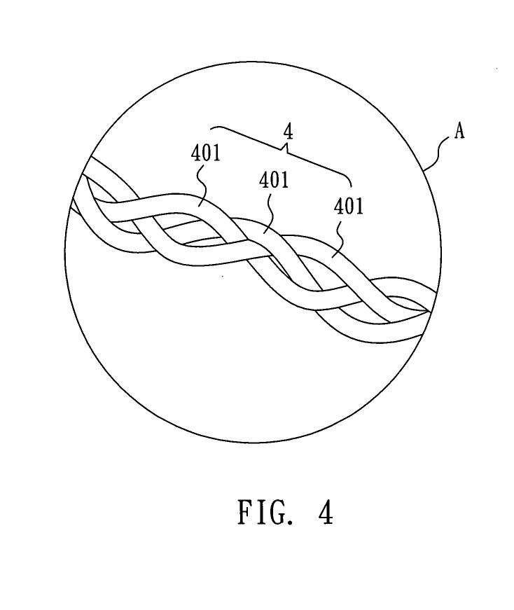

FIG. 1 is a schematic drawing of a chemical vapor deposition reactor in accordance with a first embodiment of the present invention. FIG. 4 is an enlarged view of a part of FIG. 1, showing the structure of the hot filaments.

As shown in FIG. 1, the chemical vapor deposition reactor comprises a chamber 1 for a coating work. The chamber 1 defines therein an enclosed space 11. The substrate 9 for the coating work of chemical deposition is placed on a table inside the enclosed space 11. The substrate 9 has a top surface 91 for the coating work.

Further, two electrodes 2 and 21 are bilaterally provided inside the enclosed space 11. The electrode at the right side is a rotating electrode 21 having mounted thereon six hot filaments 4. The electrode at the left side is a fixed electrode 2. As shown in FIG. 4, each hot filament 4 is formed of three twisted hot wires 401.

As illustrated, each hot filament 4 has two ends respectively connected to the fixed electrode 2 and the rotating electrode 21. The hot filaments 4 are arranged in parallel and to form a horizontal coating plane in parallel to the horizontal bottom wall of the chemical vapor deposition reactor, and spaced above the top surface 91 of the substrate 9 at a distance D1. Further, each hot filament 4 has a predetermined tension.

Further, the rotating electrode 21 has one end coupled to a rotating power source 3. According to this embodiment, the rotating power source 3 is an electric motor.

Further, a stress sensor 501 is mounted on the rotating electrode 21 to detect the tension of every hot filament 4 and to output a corresponding detection signal to an external controller 93 for computing so that the computed result is used to control the operation of the rotating power source 3 in rotating the rotating electrode 21 in a particular direction, thereby maintaining the distance D1 at a fixed value.

Thus, when the hot filaments 4 expand due to a significant temperature change during the coating work in the chamber 1, the rotating electrode 21 is rotated to stretch the hot filaments 4, maintaining a fixed distance D1 between the hot filaments 4 and the top surface 91 of the substrate 9.

According to this embodiment, the stress sensor 501 outputs a detection signal to the external controller 93 for computing. Alternatively, the stress sensor 501 can be constructed to directly feed back a detection signal to the rotating power source 3 for direct control by means of automatic control means without through the external controller 93.

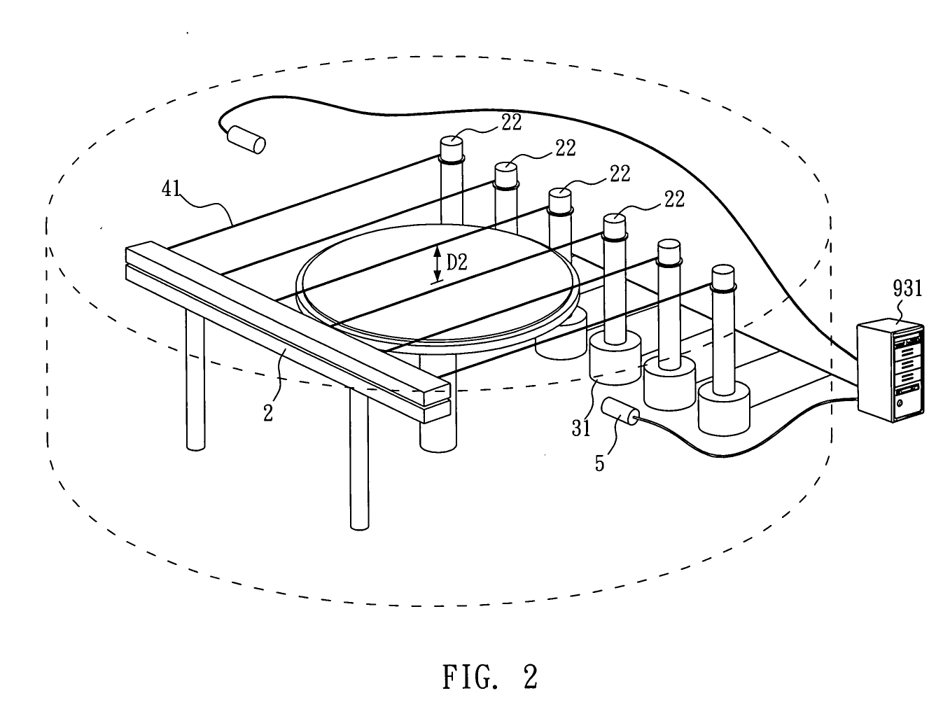

FIG. 2 is a schematic drawing of a chemical vapor deposition reactor in accordance with a second embodiment of the present invention.

This embodiment is substantially similar to the aforesaid first embodiment with the exception of the arrangement of the rotating electrode and the sensor. This second embodiment achieves the same various effects as the aforesaid first embodiment.

As shown in FIG. 2, a plurality of rotating electrodes 22 are vertically arranged at one side inside, a fixed electrode 2 is arranged at the opposite side, and hot filaments 41 are respectively connected between the vertical rotating electrodes 22 and the fixed electrode 2. Further, the rotating electrodes 22 are respectively mounted on a respective rotating power source 31. According to this embodiment, each rotating power source 31 is an electric motor.

Further, a pair of sensors 5 is provided to detect variation of the distance D2 between the top surface of the substrate and each hot filament 41, and to output a corresponding detection signal to an external controller 931 for computing. According to this embodiment, the sensors 5 are optical sensors, for example, infrared sensors or the like. Upon receipt of the detection signal from the sensors 5, the controller 931 controls the rotating power sources 31 through a wired-control method to rotate the associating rotating electrodes 22, thereby stretching every hot filament 41 to maintain the distance D2 between the top surface of the substrate and each hot filament 41 at the predetermined value.

According to this embodiment, the optical sensors 5 output a detection signal to the external controller 931 for computing. Alternatively, the optical sensors 5 can be constructed to directly feed back a detection signal to the rotating power sources 3 for direct control by means of automatic control means without through the external controller 931.

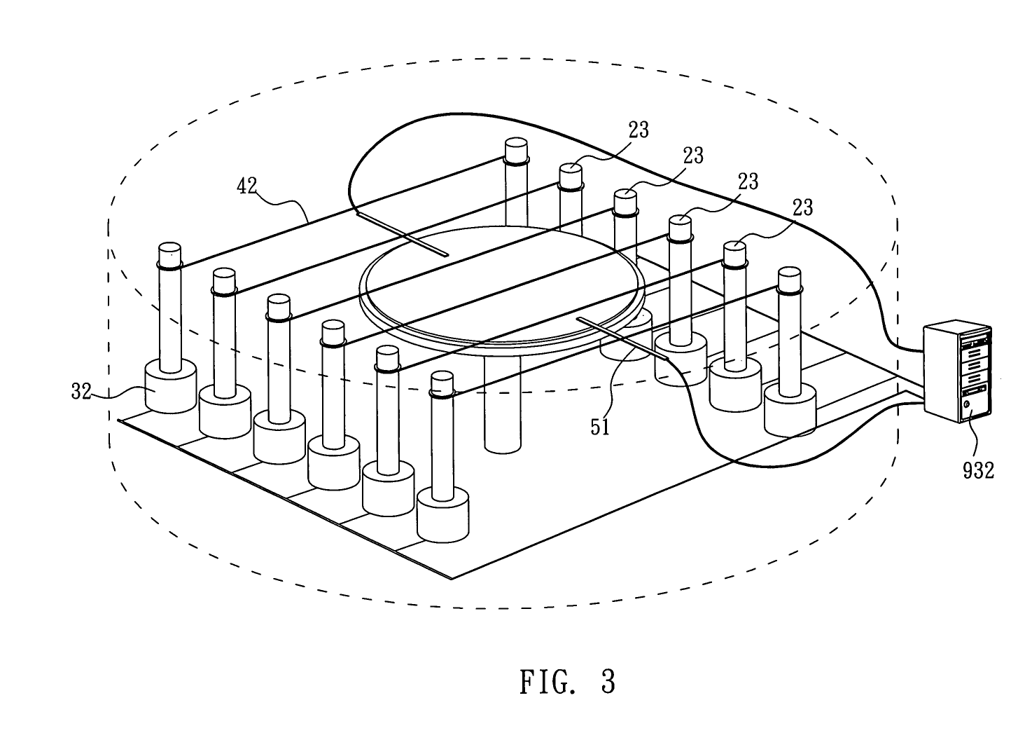

FIG. 3 is a schematic drawing of a chemical vapor deposition reactor in accordance with a third embodiment of the present invention. This embodiment is substantially similar to the aforesaid first embodiment with the exception of the arrangement of the electrodes and the sensor. This third embodiment achieves the same various effects as the aforesaid first embodiment.

As shown in FIG. 3, a plurality of vertical rotating electrodes 23 are arranged in pair at two sides, and hot filaments 42 are respectively connected between the vertical rotating electrodes 23 at the two sides. According to this embodiment, there are six pairs of vertical rotating electrodes 23 and six hot filaments 42. Further, each vertical rotating electrode 23 is respectively mounted on a respective rotating power source 32. According to this embodiment, each rotating power source 32 is an electric motor.

Further, a pair of sensors 51 is provided to detect temperature change of each hot filament 42, and to output a corresponding detection signal to an external controller 932 for computing, thereby judging the tension (expanding) of each hot filament 42. According to this embodiment, the sensors 51 are thermocouple sensors. After computing of the detection signal received from the sensors 51 and comparing of the computed result to a predetermined reference value, the controller 932 controls the rotating power sources 32 by means of a wired control method to output a rotating driving force to rotate the associating vertical rotating electrodes 23, thereby stretching the hot filaments 42 and preventing the hot filaments 42 from touching the top surface of the substrate. Therefore, this third embodiment achieves the same various effects as the aforesaid first embodiment of the present invention.

Although the present invention has been explained in relation to its preferred embodiments, it is to be understood that many other possible modifications and variations can be made without departing from the spirit and scope of the invention as hereinafter claimed.

1. A chemical vapor deposition reactor comprising:
a chamber, said chamber having an enclosed space and a substrate placed in said enclosed space, said substrate having a top surface;
at least two electrodes arranged in said enclosed space inside said chamber, said at least two electrodes including at least one rotating electrode;
a plurality of hot filaments arranged in parallel to form a horizontal coating plane, said hot filaments each having two distal ends respectively connected to said at least two electrodes, said hot filaments being respectively spaced above the top surface of said substrate at a predetermined distance, said hot filaments each having a predetermined tension; and
an electric motor connected to one end of said rotating electrode to rotate said at least one rotating electrode in one direction so as to maintain the predetermined distance between the associating hot filament and the top surface of said substrate.

2. The chemical vapor deposition reactor as claimed in claim 1, further comprising at least one optical sensor means adapted to detect variation of the distance between each of said hot filaments and the top surface of said substrate and to outputs a corresponding detection signal.

3. The chemical vapor deposition reactor as claimed in claim 2, further comprising a controller adapted to receive the detection signal outputted from said at least one optical sensor means and to control the operation of said electric motor subject to the detection signal.

4. The chemical vapor deposition reactor as claimed in claim 2, wherein said detection signal directly controls the operation of said electric motor.

5. The chemical vapor deposition reactor as claimed in claim 1, further comprising at least one stress sensor adapted to detect the variation of the tension of each of said hot filaments and to output a corresponding detection signal.

6. The chemical vapor deposition reactor as claimed in claim 5, further comprising a controller adapted to receive the detection signal outputted from said at least one stress sensor and to control the operation of said electric motor subject to the detection signal.

7. The chemical vapor deposition reactor as claimed in claim 5, wherein said detection signal directly controls the operation of said electric motor.

8. The chemical vapor deposition reactor as claimed in claim 1, further comprising at least one thermocouple sensor to detect variation of the temperature of each of said hot filaments and to output a corresponding detection signal.

9. The chemical vapor deposition reactor as claimed in claim 8, further comprising a controller adapted connected to said thermocouple sensor to receive the detection signal outputted from said at least one thermocouple sensor and to control the operation of said electric motor subject to the detection signal.

10. The chemical vapor deposition reactor as claimed in claim 8, wherein said thermocouple sensor is disposed under said hot filaments and outputs said detection signal to directly control the operation of said electric motor.

11. (canceled)

12. The chemical vapor deposition reactor as claimed in claim 1, wherein said hot filaments each are formed of a plurality of twisted hot fibers.

13. A chemical vapor deposition reactor, comprising:
a chamber having an enclosed space and a substrate placed in the enclosed space, the substrate having a surface;
an adjustment device disposed across the substrate, the adjustment device having at least two electrodes and electric motors connected to the electrodes; and
a plurality of hot filaments arranged in parallel, wherein each hot filament is connected between two of the electrodes and having a predetermined tension respectively adjusted by each of the electric motors.

14. The chemical vapor deposition reactor as claimed in claim 13, wherein the electrodes comprise at least a rotation electrode and a fixed electrode.

15. The chemical vapor deposition reactor as claimed in claim 14, wherein the rotation electrode is connected to the electric motor and the tension of each filaments is adjusted by the electric motor, the electric motor rotates the rotation electrode in a specific direction.

16. The chemical vapor deposition reactor as claimed in claim 13, further comprising a sensor disposed inside the chamber and connected to a controller.

17. The chemical vapor deposition reactor as claimed in claim 16, wherein the sensor comprises a optical sensor or a thermocouple sensor to detect variation of the distance between each of the filaments and the surface of the substrate.

18. The chemical vapor deposition reactor as claimed in claim 16, wherein the sensor comprises a stress sensor to detect the variation of the tension of each of the filaments, the stress sensor is disposed on the electrodes.

19. The chemical vapor deposition reactor as claimed in claim 16, wherein the controller is received a detection signal outputted from the sensor to control the operation of the electric motor.

20. The chemical vapor deposition reactor as claimed in claim 16, wherein a detection signal outputted from the sensor directly controls the operation of said electric motor.
